(19) United States
(12) Patent Application Publication
(10) Pub. No.: US 2023/0021319 A1
(43) Pub. Date: Jan. 26, 2023

(54) METHOD AND APPARATUS FOR ROUTING WIRES ON CHAIN QUANTUM CHIP, AND STORAGE MEDIUM

(71) Applicant: Beijing Baidu Netcom Science Technology Co., Ltd., Beijing (CN)

(72) Inventors: Lijing JIN, Beijing (CN); Boyan YU, Beijing (CN)

(21) Appl. No.: 17/894,607

(22) Filed: Aug. 24, 2022

(30) Foreign Application Priority Data
Nov. 4, 2021 (CN) 202111301748.1

(51) Int. Cl. G06N 10/40

(52) U.S. Cl. CPC G06N 10/40

(57) ABSTRACT

A method for routing wires on a chain quantum chip is provided. The method may include: encoding, according to a corresponding relationship between multiple pins of a chain quantum chip and inlets of multiple qubits on a qubit chain, the multiple pins and multiple inlets respectively, where the multiple pins include multiple first pins parallel to an extending direction of the qubit chain; determining and connecting a first inlet with a first target pin, where a distance between an abscissa of the first inlet and an abscissa of the first target pin satisfies a first preset condition; and connecting, according to codes of remaining inlets and codes of remaining pins, the remaining inlets with the remaining pins in a one-to-one correspondence.

### CROSS-REFERENCE TO RELATED APPLICATIONS

The present application claims the priority of Chinese Patent Application No. 202111301748.1, titled “METHOD AND APPARATUS FOR ROUTING WIRES ON CHAIN QUANTUM CHIP, ELECTRONIC DEVICE AND STORAGE MEDIUM”, filed on Nov. 4, 2021, the content of which is incorporated herein by reference in its entirety.

### TECHNICAL FIELD

The present disclosure relates to the field of quantum computing, particularly to the field of quantum chip design, and specifically to a method and apparatus for routing wires on a chain quantum chip, and a storage medium.

### BACKGROUND

Since the multi-layer layout technology for quantum chips is not yet mature, in the existing mainstream superconducting quantum chips, both qubits and control lines are still placed on the same layer of the same chip. Since the former quantum chips have the characteristics such as a small size, a small number of qubits and a simple layout, the former quantum chips often adopt a manual routing scheme, or a maze routing scheme borrowed from the classic very-large-scale integrated circuit design (VLSI) technology. However, as the quantum chips become more and more complex, especially the numbers of qubits in quantum chips containing a chain structure are getting larger, it is unable to continue adopting the manual or maze routing scheme to solve the routing problem of the quantum chips, especially the routing problem of a chain quantum chip containing multiple quantum chips.

### SUMMARY

The present disclosure provides a method and apparatus for routing wires on a chain quantum chip, an electronic device and a storage medium.

According to an aspect of the disclosure, a method for routing wires on a chain quantum chip is provided, which includes:

encoding, according to a corresponding relationship between a plurality of pins of the chain quantum chip and inlets of a plurality of qubits on a qubit chain, the plurality of pins and the inlets respectively, wherein the plurality of pins comprises a plurality of first pins, and the plurality of first pins are parallel to an extending direction of the qubit chain;

determining a first inlet from the plurality of inlets, and determining a first target pin from the plurality of first pins, wherein a distance between an abscissa of the first inlet and an abscissa of the first target pin satisfies a first preset condition;

connecting the first inlet with the first target pin;

connecting, according to codes of remaining inlets and codes of remaining pins, the remaining inlets with the remaining pins in a one-to-one correspondence.

With this method, the optimal solution of the wiring of the chain quantum chip can be accurately and quickly obtained. The whole process does not need human intervention, and truly realizes the automatic chip wiring, which greatly improves the efficiency of the whole superconducting quantum chip design; and this method has strong scalability. This method can be used no matter how many single qubits are included in the chain qubit.

According to another aspect of the disclosure, an apparatus for routing wires on a chain quantum chip is provided, which includes:

an encoding module, configured to encode, according to a corresponding relationship between a plurality of pins of the chain quantum chip and inlets of a plurality of qubits on a qubit chain, the plurality of pins and a plurality of inlets respectively, wherein the plurality of pins comprises a plurality of first pins, and the plurality of first pins is parallel to an extending direction of the qubit chain;

a first determining module, configured to determine a first inlet from the plurality of inlets, and determine a first target pin from the plurality of first pins, wherein a distance between an abscissa of the first inlet and an abscissa of the first target pin satisfies a first preset condition;

a first connecting module, configured to connect the first inlet with the first target pin; and

a second connecting module, configured to connect, according to codes of remaining inlets and codes of remaining pins, the remaining inlets with the remaining pins in a one-to-one correspondence.

According to another aspect of the disclose, a chain quantum chip is provided, which includes:

a qubit chain, comprising a plurality of qubits, wherein the qubit in the plurality qubit comprises at least one inlet;

a plurality of pins, corresponding to codes of a plurality of inlets of the qubit chain one by one, wherein the plurality of pins comprises a plurality of first pins, and the plurality of first pins is parallel to an extending direction of the qubit chain;

a plurality of connection wires, connecting the pins corresponding to the codes with the inlets respectively;

wherein the plurality of inlets comprises a first inlet, and the plurality of first pins comprises a first target pin, wherein a distance between an abscissa of the first inlet and an abscissa of the first target pin satisfies a first preset condition, and the plurality of connection wires comprises a first connection wire, connecting the first inlet with the first target pin.

According to another aspect of the disclosure, a non-transitory computer readable storage medium is provided, where the computer instruction is used to cause a computer to perform the method according to any one of embodiments of the disclosure.

It should be understood that the content described in this part is not intended to identify key or important features of the embodiments of the present disclosure, and is not used to limit the scope of the present disclosure. Other features of the present disclosure will be easily understood through the following description.

### BRIEF DESCRIPTION OF THE DRAWINGS

Accompanying drawings are used for a better understanding of the scheme, and do not constitute a limitation to the present disclosure. Here:

FIG. 1 is a schematic diagram of a one-dimensional chain of qubits according to some embodiments of the present disclosure;

FIG. 2 is a schematic diagram of a pin layout of a chain quantum chip according to some embodiments of the present disclosure;

FIG. 3 is a schematic flowchart of a method for routing wires on a chain quantum chip according to some embodiments of the present disclosure;

FIG. 4 is a schematic diagram of a method of matching on a chain quantum chip according to some embodiments of the present disclosure;

FIG. 5 is a schematic diagram of the method for routing wires on a chain quantum chip according to some embodiments of the present disclosure;

FIG. 6 is a schematic diagram of the method for routing wires on a chain quantum chip according to some other embodiments of the present disclosure;

FIG. 7 is a schematic diagram of the method for routing wires on a chain quantum chip according to some other embodiments of the present disclosure;

FIG. 8 is a schematic diagram of the method for routing wires on a chain quantum chip according to some other embodiments of the present disclosure;

FIG. 9 is a schematic flowchart of the method for routing wires on a chain quantum chip according to some other embodiments of the present disclosure;

FIG. 10 is a schematic diagram of an apparatus for routing wires on a chain quantum chip according to some embodiments of the present disclosure;

FIG. 11 is a schematic diagram of a chain quantum chip according to some other embodiments of the present disclosure; and

FIG. 12 is a block diagram of an electronic device adapted to implement the method for routing wires on a chain quantum chip according to some embodiments of the present disclosure.

### DETAILED DESCRIPTION OF EMBODIMENTS

Example embodiments of the present disclosure are described below in combination with the accompanying drawings, and various details of the embodiments of the present disclosure are included in the description to facilitate understanding, and should be considered as example only. Accordingly, it should be recognized by one of ordinary skill in the art that various changes and modifications may be made to the embodiments described herein without departing from the scope and spirit of the present disclosure. Also, for clarity and conciseness, descriptions for well-known functions and structures are omitted in the following description.

The term “and/or” herein is only an association relationship that describes associated objects, and represents that there may be three kinds of relationships. For example, A and/or B may mean that there is only A, there are both A and B, or there is only B. The term “at least one” herein represents any one kind in multiple kinds or any combination of at least two kinds in the multiple kinds, for example, including at least one of A, B and C, and may represent including one or more elements selected from the set composed of A, B and C. The terms “first” and “second” herein refer to and distinguish multiple similar technical terms, and are not intended to limit an order, or limit the meaning to only two, for example, a first feature and a second feature refer to that there are two types of features/two features, the first feature may be one or more features, and the second feature may also be one or more features.

In addition, in order to better describe the present disclosure, numerous specific details are given in the following specific embodiments. It should be understood by those skilled in the art that the present disclosure may be implemented without certain specific details. In some instances, methods, means, elements and circuits well known to those skilled in the art are not described in detail, so as not to obscure the subject matter of the present disclosure.

Quantum computing is a new computing mode that follows the laws of quantum mechanics to regulate quantum information units for computation. The core of quantum computing hardware is a large number of qubits connected to each other. These interconnected qubits together constitute the central processing unit of quantum computing, which we generally call a quantum processing unit (QPU). There are many different technical solutions to realize physical qubits, and a quantum processing unit is composed of a large number of interconnected physical bits. In this case, there are several schemes that may realize the integration of physical bits on a small-scale two-dimensional structure. These physical bit clusters integrated on the surfaces of silicon and sapphire are generally called quantum chips for short. Superconducting quantum chips become the current research hotspot, since the superconducting quantum chips are closest to integrated circuits and have the most mature technology.

The quantum processing unit is the same as the classical CPU, which is not a system isolated from the outside world. On the contrary, the quantum processing unit needs to exchange energy and information with the outside world. The outside world applies a specific magnetic flux or microwave signal to the qubits in the quantum chip through a read line and a control line, in order to realize the control and reading for a quantum state, thereby exchanging information. Similar to the integrated circuit, the read line and the control line do not directly touch the qubits from the outside world, but connect the edge of the chip, and then eventually transmits the signal to the qubits through a coplanar waveguide on the chip. The routing problem of the chip is actually the design problem of the coplanar waveguide on the chip.

The coplanar waveguide is a planar structure on a chip. In the present disclosure, all the “wires” (transmitting signals, energy, etc.) on the chip are coplanar waveguides, including a read line, a control line, etc. A read resonant cavity is also a structure made of coplanar waveguides. The control and read lines are made of coplanar waveguides. The coplanar waveguides are similar to but different from the “wires” that are usually concerned. The coplanar waveguide is a structure on the chip, which can realize the function of the wire, but cannot be connected arbitrarily in three-dimensional space like the wire.

In the existing technology, for a quantum chip with a simple structure, it is only required to connect the corresponding line on the qubit to the pin on the edge of the chip during routing. There are two mainstream routing approaches commonly used.

The first one is manual routing. That is, the location of each line is manually designed through the experimental experience of engineers.

The second one is maze routing scheme borrowed from the classic very-large-scale integrated circuit design (VLSI) technology. The main implementation of maze routing is a breadth-first search. First, the entire chip is gridded. Here, wires can not be arranged at a place where there is already a component, and identifiers are needed at this place in the grid. Then, a depth-first search is performed on a group of a starting point and an ending point to find a path that needs to pass through the existing structure. The grid cells that this path goes through is marked. Then, the search is performed on the next group of a starting point and an ending point until all routing is completed or the shortest path can not be found. When the shortest path cannot be found, the existing scheme is generally discarded, or the directions of several lines in the existing scheme are modified, and then the maze routing is performed again.

However, for the manual routing mentioned above, this scheme can only be applied to a quantum chip with a particularly small number of qubits and a particularly simple structure. In the case of a large number of qubits, if the manual routing scheme is still used, a lot of manpower will be consumed, and the scope of application is also limited, which makes the automation difficult. At the same time, the manual routing scheme is highly dependent on the experience of the engineers themselves, and it is difficult for this scheme to cope with new structures and new requirements.

For the maze routing scheme mentioned above, the breadth-first search itself included therein is a greedy algorithm, which cannot always guarantee to give a global optimal scheme, and sometimes cannot even give a solution. Then, for a mature structure such as a one-dimensional chain structure, the time overhead of the maze routing is too large.

As a logical necessity of breaking through classical physical limits by the chip size and a landmark technology in the post-Moore era, the quantum computing has gained a lot of attention. Nowadays, the quantum computing has made some progress whether from the application level, algorithm level, or hardware level, and faces many difficulties and challenges at the same time. At the quantum hardware level, taking the superconducting circuit widely recognized by the industrial community as an example, the charge qubit configuration of the circuit born in 1999 has a coherence time of only 1 nanosecond, and the current configuration can reach 100 microseconds, even the millisecond level. In addition, in terms of scale, chips with 50-100 superconducting qubits are also gradually mature. Here, the qubits are basic units for realizing the quantum computing. The superconducting qubits have various configurations, for example, a charge qubit, a phase qubit, and a magnetic flux qubit. Subsequently, in order to improve the coherence time of the superconducting qubits, configurations such as Transmon and X-mon (also written as Xmon) have been proposed one after another. Here, the qubit of the X-mon configuration is one of the most popular design schemes at present, and is an important qubit structure. The superconducting circuit that first achieves quantum supremacy is implemented based on the X-mon. The quantification and high efficiency of the design parameters of quantum devices are the logical necessity of breaking through and further improve the scale of qubits, and are also the basis for the realization of quantum large-scale integrated circuits. The X-mon consists of two parts: a Josephson junction and a capacitor connected in parallel with the Josephson junction. Correspondingly, the key parameters that determine the performance of the X-mon are respectively the inductance of the Josephson junction and a size of a series capacitor.

In general, a qubit needs to directly connect 1 or 2 control lines to the boundary of the chip (depending on the kind of the qubit), further needs to connect one read line to a read resonant cavity made of bent coplanar waveguides, and finally to the read bus shared by several adjacent bits. In consideration of the yield rate and the like of quantum chips, the wires on the quantum chips cannot pass through an existing structure such as a qubit, and cross each other as less as possible. The routing problem is to handle how to come up with a scheme which enables the wires on the chip to connect the bits and the boundaries of the chip, while meeting the above requirements and constraints as far as possible.

A one-dimensional chain is a configuration in which all qubits are arranged along one straight line. In the art, a one-dimensional qubit chain is often directly referred to as a qubit chain. Adjacent qubits have natural capacitive coupling, which facilitates the realization of a two-bit quantum gate. In general, the qubits on a one-dimensional chain are mainly X-mon (a form of the qubits mentioned above), because X-mon has multiple ends to facilitate capacitive coupling. For transmon (an other form of the qubits), the one-dimensional chain configuration can also be used theoretically.

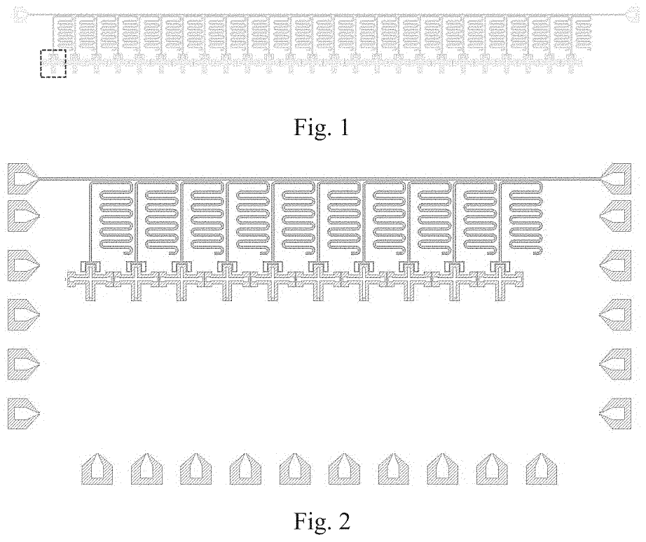

As shown in FIG. 1, in a one-dimensional chain configuration, multiple bits are generally connected to a given read line through their respective resonant cavities, and this read line is generally parallel to the straight line where the one-dimensional chain is. The cross-shaped structure circled by the dashed line in the drawing is an X-mon qubit. The qubit has four ends, and the four ends are not completely equivalent. Only one end has a Josephson junction (lower portion of the figure), which can be understood as the core of the qubit, and the other three ends are used to interact with other qubits. In two control lines, one of the control lines needs to interact with the Josephson junction, and thus needs to be placed at the lower portion, and the other one can be placed at a side of the one-dimensional chain configuration. In the disclosure, there is only an inlet location on the cross, and no outlet location, because the external wiring is not soldered to the X-mon. The one-dimensional chain in the drawing includes 25 X-mon qubits; the straight line above the X-mon qubits is a read bus, and the structure between the read line and the qubit is resonant cavities.

The present disclosure does not involve the settings of the read line and the resonant cavities. By default, before the routing, the read line and the resonant cavities already exist and are on one side of the chip. In such routing, pins (also called outlets, the pins in the examples of the present disclosure are all pentagonal) will be mainly set on the other three sides of the rectangular chip, as shown in FIG. 2. Depending on the locations of the two pins of the read line, the area on which the routing can be performed is generally the part of the chip other than the one-dimensional chain, that is, the area enclosed by the pins on the left, right and lower sides and the qubit chain in FIG. 2.

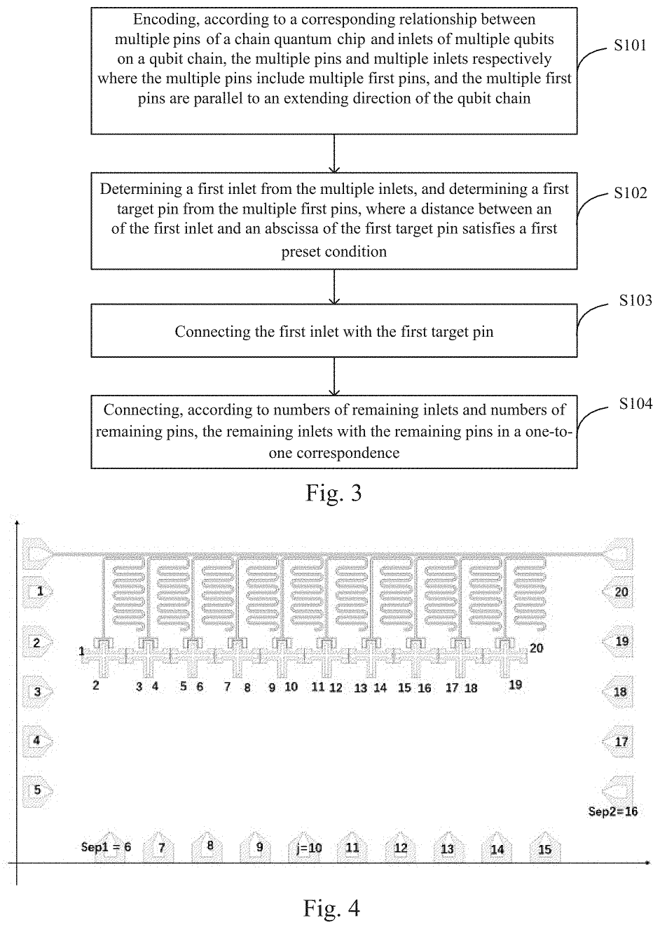

In the present disclosure, an automated implementation in which wires on a quantum chip containing a qubit chain structure can be efficiently and accurately routed is designed, that is, a method for routing wires on a chain quantum chip (also called a chain superconducting quantum chip) is provided. Specifically, with reference to FIG. 3, FIG. 3 is a flowchart of a method for routing wires on a chain quantum chip provided in some embodiments of the present disclosure. The method may include the following steps.

Step S101 includes encoding, according to a corresponding relationship between multiple pins of a chain quantum chip and inlets of multiple qubits on a qubit chain, the multiple pins and multiple inlets respectively, where the multiple pins include multiple first pins, and the multiple first pins are parallel to an extending direction of the qubit chain.

In an example, matching is performed on the multiple pins of the chain quantum chip and the inlets of the multiple qubits on the qubit chain in the order from left to right, as shown in FIG. 4, or the matching may be performed in the order from right to left, which is not specifically limited in the present disclosure. On the chain quantum chip, the multiple pins arranged along the bottom edge are defined as first pins, and the first pins are parallel to the extending direction of the qubit chains.

Step S102 includes determining a first inlet from the multiple inlets, and determining a first target pin from the multiple first pins, where a distance between an abscissa of the first inlet and an abscissa of the first target pin satisfies a first preset condition.

In an example, the first preset condition may be that the abscissa of an inlet is closest to the abscissa of the pin corresponding to the inlet, and thus, an inlet and a corresponding pin having an abscissa closest to the abscissas of the inlet are selected as the first inlet and the first target pin, and the corresponding numbers are recorded. Here, the first target pin must be one of the pins arranged along the bottom edge. As shown in FIG. 4, the numbers of the first inlet and the first target pin are 10. The first preset condition may alternatively be set according to an actual situation, for example, the distance between the abscissa of the inlet and the abscissa of the pin corresponding to the inlet is less than a specific threshold, and thus, a unique group of an inlet and a pin is selected.

Step S103 includes connecting the first inlet with the first target pin.

Step S104 includes connecting, according to numbers of remaining inlets and numbers of remaining pins, the remaining inlets with the remaining pins in a one-to-one correspondence.

In an example, the inlets and the corresponding pins are connected according to a one-to-one corresponding relationship. Here, connection wires extends in a vertical or horizontal direction, and the connection wires do not intersect with each other.

It should be noted that the principle that the scheme of performing routing wires on the chain quantum chip mainly follows is mainly to divide a right-angled trapezoid and process by the direction of an outlet. Dividing the right-angled trapezoid refers to that the shortest path is found in each direction, and then routing is respectively performed on both sides of the path. Processing by the direction of the outlet refers to that processing is respectively performed in the left direction, the downward direction and the right direction.

It is worth noting that, when the scheme in the present disclosure is explained, the distance and interval are fixed merely for the aesthetics of the routing, which also is easy to show the focus of the solution. In practice, this scheme is still applicable if a self-defined distance is used. At the same time, although the case of Xmon is used as an example, this scheme is also applicable to transmon.

The routing performed using the above example can have the following advantages:

1. High automation, and improvement of a routing efficiency. By using the above method, the automatic routing can be realized, and the chip designer and the experimenter can avoid complicated manual routing, saving resources and costs. In addition, as an important part of the quantum chip design, the one-dimensional chain design has an automatic one-dimensional chain routing scheme, which greatly improves the efficiency of the whole process design of the entire superconducting quantum chip.

2. Strong expansibility. The qubit chain is easy to expand. For an extended one-dimensional chain, the routing can be performed according to the number of qubits of the extended one-dimensional chain during a calculation. Moreover, a new structure may be constructed by arranging a two-dimensional structure into a one-dimensional chain. In this case, after being modified, the one-dimensional chain routing scheme can also be migrated and applied.

3. High stability. This scheme is more stable than the maze algorithm which is unstable and may need to be restarted again, and always gives an acceptable routing scheme.

In an example, the above step S103 specifically includes: connecting the first inlet with the first target pin through a first intermediate point. The ordinate of the first intermediate point satisfies:

y1=y_bot+1+2*r (1).

Here, in the formula (1), y_bot refers to an ordinate of the first pins. Since the multiple first pins are parallel to the extension direction of the qubit chain, the ordinates of the first pins are all equal. Here, r is a routing turning radius, and 1 is a minimum routing length. Specifically, during the routing, the wire comes out from the first inlet, goes to the first intermediate point along the vertical direction, the abscissa of the first intermediate point being the same as the abscissa of the first inlet, then the wire turns and extends to the first target pin along the horizontal direction, and turns again to connect the first target pin. Thus, two turning radii are here taken into account during the calculation. Using this example, specific routing can be performed after the inlet and the corresponding pin having the abscissas closest to the abscissas of the inlet are determined. This wire is the shortest line in the vertical direction. By using the way of passing through the first intermediate point, the wire can be quickly and accurately determined, and moreover, the wire does not intersect the rest of the routed wires.

In an example, the above step S104 specifically includes: connecting each remaining first pin to an inlet having a code corresponding to the remaining first pin respectively through a corresponding second intermediate point and a corresponding third intermediate point. The ordinates of the second intermediate point and third intermediate point connected with the remaining first pin satisfy:

y2=((j−p)*y_in+(p−1)*y_bot)/(j−1) (2).

In the above formula (2), j is the code of the first target pin, p is the code of the remaining first pin, the value of p is different in a calculation of wiring of a different pin, y_in is the ordinate of the inlet connected with the remaining first pin, and the values of the ordinates of all the inlets are equal. In an example, the wire comes out from any inlet corresponding to the remaining first pin, goes to the second intermediate point along the vertical direction, then turns to the direction of the corresponding pin, goes to the third intermediate point, of which the x value is equal to the x value of the corresponding pin, in the horizontal direction, and then turns from the third intermediate point and goes straight in the vertical direction to the corresponding pin. By using this example, wiring may be performed on the remaining pins on the bottom edge, and the wiring can be performed accurately and quickly without generating an intersection between the wires.

In an example, the multiple pins include multiple second pins, and the multiple second pins are located on one side of the qubit chain and are perpendicular to the extending direction of the qubit chain. As shown in FIG. 4. 1-5 and 16-20 belong to the second pins, that is, the pins arranged on the left or right side of the chip are the second pins.

In an example, step S104 specifically includes: determining a second inlet from the multiple inlets, and determining a second target pin and a third target pin from the multiple second pins. Here, the code of the third target pin is adjacent to the code of a first pin farther away from the first target pin, and the distance between the ordinate of the fourth intermediate point corresponding to the second inlet and the ordinate of the second target pin satisfies a second preset condition. Here, the ordinate of the fourth intermediate point corresponding to the second inlet satisfies:

y3=((j−p1)*y_in1+(p1−1)*y_out1)/(j−1) (3).

In the above formula (3), p1 is the code of the second target pin, y_in1 is the ordinate of the second inlet, y_out1 is the ordinate of the third target pin, and the third target pin is actually the pin closest to the bottom edge and having the smallest ordinate, for pins on the side edge.

Satisfying the second preset condition actually refers to that an inlet and a pin belonging to the pins on the side edge, satisfying the preset condition, are found according to the preset condition. In an example, all the wires connected to the pins on the side edge need to go vertically by a length first, and then turn to the side edge. Therefore, first, through the formula (3), the ordinates of the intermediate points after the wires go vertically are calculated. Then, a pair of an inlet and a pin having a shortest distance in the vertical direction is found. The second preset condition may alternatively be a threshold, and a pair of an intermediate point and a corresponding pin of which the ordinates satisfy the threshold is found, which is not limited herein.

Step S104 includes: connecting the second inlet with the second target pin through the fourth intermediate point; and

connecting, according to codes of current remaining inlets and codes of remaining second pins, the current remaining inlets with the remaining second pins in a one-to-one correspondence.

In an example, the second inlet and its corresponding second target pin are determined, and the second target pin is one of the second pins. As shown in FIG. 4, the number of the second target pin in this example is 3. The second inlet and its corresponding second target pin are a pair of an inlet and a pin of which the ordinates are closest. During the routing, the wire goes to the fourth intermediate point along the vertical direction, then turns to the direction of the corresponding pin, and goes to another intermediate point along the horizontal direction, the x value of the intermediate point being:

x=x_out_left+2*r+dx (4).

Here, r is a turning radius, dx is the minimum line length on the horizontal axis, and x_out_left is the abscissa of the second pin. Then, the wire turns toward the direction of the corresponding pin, and goes to the next intermediate point along the vertical direction, the y value of the intermediate point being:

y=y_out[p]+r (5).

Here, y_out[p] refers to the ordinate of a p-th pin.

The wire turns and then goes by dx along the horizontal direction to reach the corresponding pin. By using this scheme, the shortest wire to the pins on the side edge can be found most quickly and accurately. Next, this wire is used as the boundary to give multiple areas for respective routing, which lays the foundation for the subsequent routing on a side.

In an example, a fourth target pin is determined from the multiple first pins. Here, the code of the fourth target pin is adjacent to a second pin farther from the second target pin, that is, the fourth target pin is a pin closest to the side edge among the pins on the bottom edge.

Each second pin between the second target pin and the fourth target pin is connected to an inlet having a code corresponding to the second pin respectively through a corresponding fifth intermediate point and a corresponding sixth intermediate point. The ordinates of the fifth intermediate point and the sixth intermediate point satisfy:

y4=((j−p2)*y_in2+(p2−1)*y_out1)/(j−1) (6).

Here, p2 in the formula (6) is the code of the second pin between the second target pin and the fourth target pin, and y_in2 is the ordinate of an inlet corresponding to the second pin between the second target pin and the fourth target pin.

The abscissa of the sixth intermediate point satisfies:

x1=((p2−i)*x_left+(sep1−p2)*x_out_left)/(sep1−i) (7).

In the formula (7), i is the code of the second target pin, x_left is the abscissa of the fourth target pin, sep1 is the code of the fourth target pin, and x_out_left is the abscissa of the second pin.

In an example, after coming out from the inlet, the wire goes to the fifth intermediate point along the vertical direction, then turns toward the direction of the corresponding pin, goes to the sixth intermediate point along the horizontal direction, then turns toward the direction of the corresponding pin, goes along the vertical direction to the location at the same height as the corresponding pin, and then turns and extends along the horizontal direction to the corresponding pin. By using this scheme, the routing can be automatically performed on the pins at a lower portion of left and right sides, and thus the routing is quickly and accurately performed.

In an example, a third inlet is determined from the multiple inlets, the third inlet facing the column where the second pins are. The pin corresponding to the code of the third inlet is determined as a fifth target pin, that is, the pin corresponding to a lateral inlet of a qubit at the end of the qubit chain is used as the fifth target pin.

Each second pin between the second target pin and the fifth target pin is connected to an inlet having a code corresponding to the second pin respectively through a corresponding seventh intermediate point and a corresponding eighth intermediate point. The ordinates of the seventh intermediate point and the eighth intermediate point satisfy:

y5=((j−p3)*y_in3+(p3−1)*y_out1)/(j−1) (8).

In the formula (8), p3 is the code of the second pin between the second target pin and the fifth target pin, and y_in3 is the ordinate of an inlet corresponding to the second pin between the second target pin and the fifth target pin.

The abscissa of the eighth intermediate point satisfies:

x2=(p3*x_out_left+(i−p3)*x_0)/i (9).

In the formula (9), x_0 is the coordinate of an end point of the qubit chain, the end point being closer to the second pin.

The fifth target pin is connected to the third inlet through a ninth intermediate point. The abscissa of the ninth intermediate point satisfies:

x3=(x_out_left+(i−1)*x_0)/i (10).

By using this example, when the inlet does not face the side edge, the wire first goes to the seventh intermediate point vertically during the routing, then turns and goes to the eighth intermediate point along the horizontal direction, then turns and goes vertically to the location at the same height as the ordinate of the corresponding pin, and then turns and reaches the destination to connect the corresponding pin.

When the inlet faces the side edge, the wire first goes to the ninth intermediate point along the horizontal direction, then turns and goes along the vertical direction to the location at the same height as the ordinate of the corresponding pin, and then turns and connects the corresponding pin.

By using this example, routing can be automatically performed for the pins at an higher portion at left side and right side, and during the routing, a situation that an inlet at an end of the chain may have an outlet facing the end of the chain is considered, thus the routing is performed in consideration of different outlet directions, which ensures that the routing result is more accurate.

It should be noted that the method of performing routing on the side edge in the above example can be used on the pins on the left or right side of the chip. During the actual routing, the routing on one side is generally first completed, and the routing on the other side can be performed in the same way. For the details, reference may be made to the following specific scheme.

It should be further noted that, if the pins on the chip are strictly symmetrical about an axis, the one-dimensional qubit chain is also symmetrical about an axis, and the symmetry axis coincides with the symmetry axis of the pins, then it is possible to only calculate the routing on one half of the chip. The corresponding routing on the other half is completely obtained in a mirror-symmetrical manner without repeated calculations, which further improves the routing efficiency.

A specific scheme in which some embodiments of the present disclosure are applied includes the following content.

Step 1: performing preprocessing to determine the outlet location of a read line at an edge of a chip.

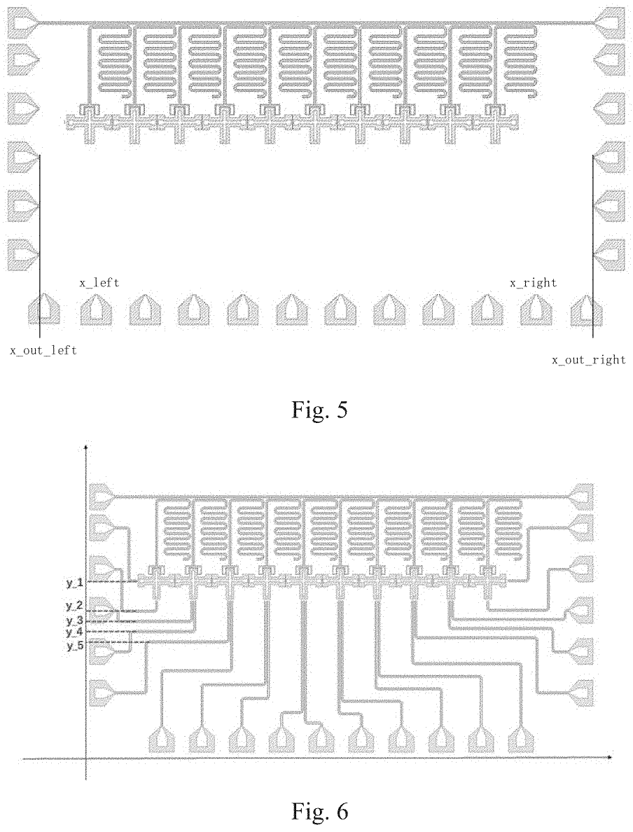

In this step, on the basis that there is a read line, resonant cavities and a one-dimensional qubit chain, pins are arranged and locations are recorded, as shown in FIG. 5, this step specifically including the following steps.

a) Pin locations are assigned. First, as an example, each qubit connects 2 control lines. According to the principle of equal spacing, for a one-dimensional chain of X-mon qubits, 2*n (n is the number of qubits)+2*m (2*m is the number of extra pins, also referred to as placeholder pins, in order to leave space at the bottom boundary for the next step) pins are arranged and routed on the three boundaries of the remaining area of a routable rectangle (left, bottom and right sides of the chip). As shown in FIG. 5, there are a total of 10 X-mon qubits. If 2 control lines are routed for each qubit, 20 corresponding pins are required. However, 22 unwired pins are disposed in FIG. 5. Among the multiple pins arranged along the bottom side of the chip, the two pins at two ends are used as extra pins for connecting with other chips. It should be especially pointed out that 10 qubits are selected in this example only for the convenience of drawing and calculation, and this scheme also allows solving in the case of other numbers of qubits and user-defined distances. Similarly, the selection that each qubit has two connection wires is also for the convenience of drawing and calculation, and this scheme also allows each qubit to have one or more connection wires.

b) M pins are respectively removed from the left and right corners of the bottom edge. In the remaining pins on the bottom edge, the abscissas of the leftmost and rightmost pins are marked as x_left and x_right.

c) The abscissas of all pins on the left side are uniformly marked as x_out_left, and the abscissas of all pins on the right side are uniformly marked as x_out_right.

Step 2: recording relevant parameters (also referred to as calibration boundaries)

In this step, the relevant parameters of all inlets on the X-mon qubit and the corresponding pins are obtained, including:

a) According to the principle from left to right, the corresponding inlet location on Xmon is found for each pin, and encoding (also called inlet numbering) is performed based on the corresponding relationship, as shown in FIG. 4. Then, the coordinates of all inlets and pins on the chip are recorded. For example, the abscissa of a p-th inlet is recorded as x_in[p], the abscissa and ordinate of a p-th pin are recorded as x_out[p] and y_out[p], and the ordinates of all pins on the bottom edge are equal, and recorded as y_bot.

b) The number of the leftmost pin on the bottom edge is recorded as sep1 (sep1=6 in the present disclosure), and the number of the bottommost pin on the right edge is recorded as sep2 (sep2=16 in the present disclosure).

c) A pin of which the abscissa is closest to the corresponding inlet is selected from the pins on the bottom edge. The number of this pin is recorded as j, as shown in FIG. 4. In this example, j=10. If there are two pins of which the abscissas have the same distance to the corresponding inlet, a smaller one of the numbers of the two pins is selected as j.

d) It should be noted that the X-mon qubits have two types of inlets. The first type of inlet is a side inlet, and only the qubits at two ends of the one-dimensional chain have this type of inlet. The second type is down-side inlet. All qubits in the one-dimensional chain have the down-side inlet, and the ordinates of the down-side inlets of all qubits on the one-dimensional chain are equal, recorded as y_in. The ordinate of an outlet on the bottom edge is recorded as y_bot. For the p-th inlet (also the p-th pin) between 1 and sep1, the ordinate y_p of the routing intermediate point corresponding to the p-th pin is calculated using the following formula:

y_p=((j−p)*yᵢₙ+(p−1)*y_out[sep1−1])/(j−1).

In this example, j=10, y_in is the ordinate of the qubit on the one-dimensional chain, and y_out[sep1−1] refers to the ordinate of the pin being on the left edge and being closest to the bottom edge, and in this example, refers to the ordinate of the pin with a number of 5. Referring to FIG. 6, it can be seen that the ordinates y_2−y_5 corresponding to the 2nd to 5th pins can be quickly calculated by the above formula.

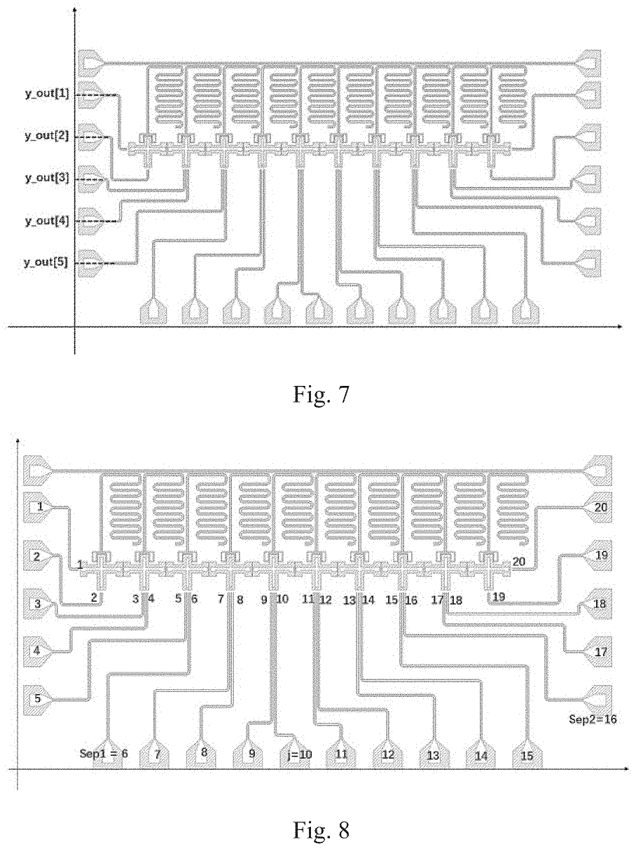

e) A pin of which the ordinate is closest to (shortest route) the ordinate y_p of the corresponding routing intermediate point is selected from the pins on the left side, and its number is recorded as i. As shown in FIG. 7, the ordinates of all the pins on the left side are annotated as y_out[p], and it is determined that i=3 in this example, after y_out[p] is compared with y_p.

f) In the same way as on the left side, it is found on the right side that the number corresponding to the shortest route is k. In this example, k=18.

g) The abscissas of two ends of the one-dimensional chain are x_0 and x_1, the turning radius is r, the minimum routing length in the horizontal direction is dx and the minimum routing length in the vertical direction is dy, and the minimum routing lengths may both be 1 regardless of the horizontal direction or the vertical direction. It should be noted that the turning radius can be ignored during the routing since the turning radius is relatively small, except in c), f) and i) in Step 3.

Step 3: routing wires, including routing wires on the left side and routing wires on the right side. As shown in FIG. 8, for inlets and pins that have different numbers, different formulas are applied to perform routing. It should be emphasized that, during the routing in the present disclosure, the sequential order of the routing is not defined, that is, the inlet and the corresponding pin that are to be first routed can be arbitrarily selected, which is within the scope of protection of the present disclosure. It should be noted that the angles of the turnings in the present disclosure are all 90°.

a) p=1 (the first wire in the top left corner):

i. The wire goes to the first intermediate point along the horizontal direction. Here the y value of the intermediate point is equal to the y value of the corresponding inlet, and the x value is: x=(x_out_left+(i−1)*x_0)/i.

ii. The wire turns toward the direction of the pin numbered 1, and goes to the second intermediate point along the vertical direction. The y value of this intermediate point is: y=y_out[1]. Here, y_out[1] is the ordinate of the pin numbered 1.

iii. The wire turns, and goes straight along the horizontal direction until the wire connects the corresponding pin.

In this step, the first wire in the top left corner is routed, and in this case, p=1. The wire goes toward left side first, then turns right to go upward, and finally turns left to reach the pin.

b) 1<p<i (the second wire in the top left corner to the shortest wire at the left side; the first right-angled trapezoid on the top left side, which corresponds to the connection wire between the inlet numbered 2 and the pin in this example):

i. The wire goes to the first intermediate point along the vertical direction. The x value of this intermediate point is the x value of the corresponding inlet, and the y value is: y=((j−p)*y_in+(p−1)*y_out[sep1−1])/(j−1). Here, y_out[sep1−1] is the y value of the last pin on the left side.

ii. The wire turns toward the direction of the corresponding pin, and goes to the second intermediate point along the horizontal direction. The x value of this intermediate point is: x=(p*x_out_left+(i−p)*x_0)/i.

iii. The wire turns toward the direction of the corresponding pin, and goes to the third intermediate point along the vertical direction. The y value of this intermediate point is: y=y_out[p], that is, the ordinate of the corresponding pin.

iv. The wire turns toward the direction of the corresponding pin, and reaches the destination to connect the corresponding pin.

In FIG. 8, this step refers to the situation where p=2. In this situation, the wire first turns right twice, and then turns left to reach the target. The wire shown in the drawing first goes downward, then turns right, then turns right to go upward, and turns left when the y coordinate of the wire is the same as the target, to reach the target.

c) p=i (the shortest path at the left side, i=3 in this example):

i. The wire goes to the first intermediate point along the vertical direction. The x value of this intermediate point is the x value of the corresponding inlet, and the y value is: y=((j−p)*y_in+(p−1)*y_out[sep1−1])/(j−1).

ii. The wire turns toward the direction of the corresponding pin, and goes to the second intermediate point along the horizontal direction. The x value of this intermediate point is: x=x_out_left+2*r+dx. Here, r is the turning radius, and dx is the minimum line length.

iii. The wire turns toward the direction of the corresponding pin, and goes to the third intermediate point along the vertical direction. The y value of this intermediate point is: y=y_out[p]+r.

iv. The wire turns, and then goes by dx along the horizontal direction to reach the corresponding pin.

This step refers to the situation where p=i (the shortest wire at the left side, i=3 in this example). In this situation, the wire first turns right, then goes straight until the x coordinate is very close to the target, and finally turns right and then left to reach the target.

d) i<p<sep1 (the remaining wires at the left side, the second right-angled trapezoid, which corresponds to the connection wires between the inlets numbered 4 or 5 and the pins in this example):

i. The wire goes to the first intermediate point along the vertical direction. The x value of this intermediate point is the x value of the corresponding inlet, and the y value is: y=((j−p)*y_in+(p−1)*y_out[sep1−1])/(j−1).

ii. The wire turns toward the direction of the corresponding pin, and goes to the second intermediate point along the horizontal direction. The x value of this intermediate point is: x=((p−i)*x _left+(sep1−p)*x_out_left)/(sep1−i).

iii. The wire turns toward the direction of the corresponding pin, and goes to the third intermediate point along the vertical direction. The difference between the y value of this intermediate point and the y value of the outlet y_out[p] is r.

iv. The wire turns toward the direction of the corresponding pin, and goes along the horizontal direction until the wire reaches the corresponding pin.

This step refers to the situation where p<6 (p>i). In this situation, the wire first goes straight to the point where the wire will not intersect with a previous wire if turning right, then turns right, then turns left to go downward to reach a position having the y-coordinate of the target, and finally turns right to reach the corresponding pin.

e) sep1<=p<j (routing wires on a left portion of the middle part of the chip:

the leftmost wire on the middle part to the shortest wire on the middle part; the third right-angled trapezoid, which corresponds to the connection wires between the inlets numbered 6-9 and the pins in this example):

i. The wire goes to the first intermediate point along the vertical direction. The x value of this intermediate point is the x value of the corresponding inlet, and the y value is: y=((j−p)*y_in+(p−1)*y_bot)/(j−1).

ii. The wire turns toward the direction of the corresponding pin, and goes to the second intermediate point along the horizontal direction. The x value of this intermediate point is: x=x_out[p].

iii. The wire turns toward the direction of the corresponding pin, and goes straight along the vertical direction until the wire reaches the corresponding pin.

In this step, the wire goes downward first to a position father than a previous wire such that the wire will not interact with the previous wire if turning right, then turns right and goes forward until x coordinate of the wire is the same as the x-coordinate of the outlet, and then turns left to go downward to reach the corresponding pin.

f) p=j (the shortest path in the middle, j=10 in this example):

i. The wire goes to the first intermediate point along the vertical direction. The x value of this intermediate point is the x value of the corresponding inlet, and the y value is: y=y_bot+dy+2*r.

ii. The wire turns toward the direction of the corresponding pin, and then goes straight to a position, of which the X coordinate has a difference r from the X coordinate x_out[j] of the outlet.

iii. The wire turns left or right to the downward direction, go straight by dy to reach the corresponding pin. Here, dy is the minimum routing length in the vertical direction, and is alternatively replaced by 1 in some cases.

This step refers to the situation where p=j (the shortest route). In this situation, the wire first goes downward to a location very close to the outlet, then turns left to be aligned with the x coordinate of the outlet, and then turns right to go downward to reach the corresponding pin.

g) j<p<sep 2 (right-side routing in the middle part of the chip: from the shortest wire in the middle to the rightmost wire in the middle part of the chip; the fourth right-angled trapezoid, which corresponds to the rightmost wire numbered 15 in this example):

i. The wire goes to the first intermediate point along the vertical direction. The x value of this intermediate point is the x value of the corresponding inlet, and the y value is: y=((p−j)*y_in+(2*n−p)*y_bot)/(2*n−j). Here, n is the number of qubits, and 2*n is the number of outlets or the number of wires.

ii. The wire turns toward the direction of the corresponding pin, and goes to the second intermediate point along the horizontal direction. The x value of this intermediate point is: x=x_out[p].

iii. The wire turns toward the direction of the corresponding pin, and goes straight along the vertical direction to reach the corresponding pin.

This step refers to the situation where j<p<sep2. In this situation, the wire goes downward first to leave enough space for the next wire such that the wire will not intersect with the next wire if turning left, then turns left to be aligned with the x-coordinate of the outlet, and then turns right to go downward to reach the corresponding pin.

h) sep2<p<k (the wires at the lower portion of the right side, the fifth right-angled trapezoid, which corresponds to the connection wires between the inlets numbered 16 and 17 and the pins in this example):

i. The wire goes to the first intermediate point along the vertical direction. The x value of this intermediate point is the x value of the corresponding inlet, and the y value is: y=((p−j)*y_in+(2*n−p)*y_out[sep2])/(2*n−j).

ii. The wire turns toward the direction of the corresponding pin, and goes to the second intermediate point along the horizontal direction. The x value of this intermediate point is: x=((p−sep2+1)*x_out_right+(k−p)*x_out_right)/(k−sep2+1).

iii. The wire turns toward the direction of the corresponding pin, and goes to the third intermediate point along the vertical direction. The y value of this intermediate point is: y=y_out[p].

iv. The wire turns toward the direction of the corresponding pin, and goes along the horizontal direction until the wire reaches the corresponding pin.

This step refers to the situation where sep2<p<k. In this situation, the wire goes straight first to leave enough space, and then turns left at a location where the wire will not intersect with the next wire if turning left. Then, the wire turns right to go downward to reach a position with the y-coordinate of the target, and finally turns left to reach the corresponding pin.

i) p=k (the shortest path at the right side, k=18 in this example):

i. The wire goes to the first intermediate point along the vertical direction. The x value of this intermediate point is the x value of the corresponding inlet, and the y value is: y=((p−j)*y_in+(2*n−p)*y_out[sep2])/(2*n−j).

ii. The wire turns toward the direction of the corresponding pin, and goes to the second intermediate point along the horizontal direction. The x value of this intermediate point is: x=x_out_right−2*r−dx.

iii. The wire turns toward the direction of the corresponding pin, and goes to the third intermediate point along the vertical direction. The y value of this intermediate point is: y=y_out[p]+r.

iv. The wire turns, and then goes by dx along the horizontal direction to reach the corresponding pin.

This step refers to the situation where p=k (the shortest wire at the right side, k=18 in this example). In this situation, the wire first turns left, then goes straight until the x coordinate is very close to the target, and finally turns left and then right to reach the target.

j) k<p<2*n (the second wire in the top right corner to the shortest wire at the right side; the first right-angled trapezoid in the top right side, which corresponds to the connection wire between the inlet numbered 19 and the pin in this example):

i. The wire goes to the first intermediate point along the vertical direction. The x value of this intermediate point is the x value of the corresponding inlet, and the y value is: y=((p−j)*y_in+(2*n−p)*y_out[sep2])/(2*n−j).

ii. The wire turns toward the direction of the corresponding pin, and goes to the second intermediate point along the horizontal direction. The x value of this intermediate point is: x=((2*n−p+1)*x_out_right+(p−k)*x_1)/(2*n−k+1).

iii. The wire turns toward the direction of the corresponding pin, and goes to the third intermediate point along the vertical direction. The y value of this intermediate point is: y=y_out[p].

iv. The wire turns toward the direction of the corresponding pin, and reaches the destination to connect the corresponding pin.

This step refers to the situation where k <p<2n. In this situation, the wire first goes straight to a location where the wire will not intersect with the previous wire if turning left, which leaves enough space for the next wire at the same time, turns left then turns left to go upward to a position with the y-coordinate of the target, and finally turns to reach the outlet.

k) p=2*n (the first wire in the top right corner):

i. The wire goes to the first intermediate point along the horizontal direction. Here, the y value of the intermediate point is equal to the y value of the corresponding inlet, and the x value is: x=(x_out_right+(2*n−k)*x_1)/(2*n−k+1).

ii. The wire turns toward the direction of the pin numbered 2*n, and goes to the second intermediate point along the vertical direction. The y value of this intermediate point is: y=y_out[2*n].

iii. The wire turns, and goes straight along the horizontal direction until the wire connects the corresponding pin.

This step refers to the situation where p=2n. In this situation, the wire is the first wire in the top right corner. This wire goes toward right side first, then turns left to go upward, and finally turns right to reach the corresponding pin.

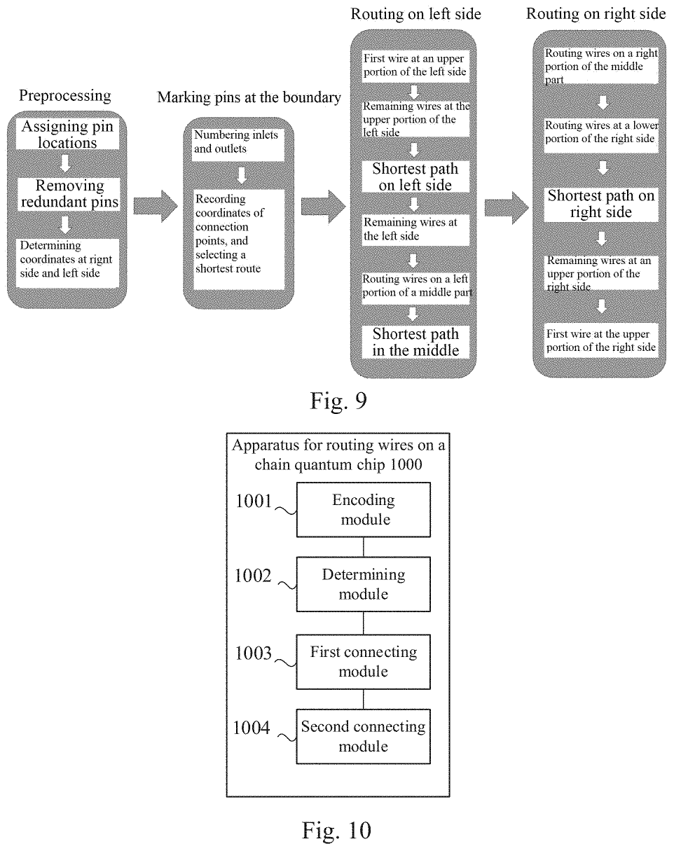

By now, the routing is completed, and the entire process of the routing is as shown in FIG. 9, including: preprocessing, boundary calibration, left-side routing and right-side routing. The above is the routing scheme of ten qubits in a one-dimensional chain. By using this disclosed scheme, the complete automation of the whole routing process can be realized. In the future, this scheme not only can be applied to one-dimensional chains with different numbers of qubits, but also can be expected to be extended to other chain structures, or adapted to chips with more complex shapes, thus improving the overall efficiency of the superconducting quantum chip design. It should be emphasized that if the arrangement of the pins and qubits satisfies the axis symmetry, the routing can be performed on the wires on one half of the chip according to the above method, and the corresponding routing path on the other half is directly obtained by mirror symmetry.

The above routing scheme not only can be applied to one-dimensional chains with different numbers of qubits, but also can be expected to be extended to other chain structures, or adapted to chips with more complex shapes, thus improving the overall efficiency of the superconducting quantum chip design. Through the automated one-dimensional chain routing method described above, chip designers and experimenters can avoid complicated manual routing, saving resources and costs. In addition, as an important part of the quantum chip design, an automatic one-dimensional chain routing scheme is achieved, the efficiency of the whole process design of the entire superconducting quantum chip is greatly improved. Considering that the one-dimensional qubit chain is easy to be expanded, when there is a one-dimensional chain of a different length, the number of qubits in the one-dimensional chain can be changed. Moreover, a new structure can be constructed by arranging some two-dimensional structures into a one-dimensional chain. In this case, after being modified, the one-dimensional chain routing scheme can also be migrated and applied. This scheme is more stable than the maze algorithm which is unstable and may need to be re-started in the existing technology, and always gives an acceptable solution.

As shown in FIG. 10, some embodiments of the present disclosure provides an apparatus 1000 for routing a chain quantum chip. The apparatus includes:

an encoding module 1001, configured to encode, according to a corresponding relationship between multiple pins of a chain quantum chip and inlets of multiple qubits on a qubit chain, the multiple pins and multiple inlets respectively, where the multiple pins includes multiple first pins, and the multiple first pins are parallel to an extending direction of the qubit chain;

a first determining module 1002, configured to determine a first inlet from the multiple inlets, and determine a first target pin from the multiple first pins, where a distance between an abscissa of the first inlet and an abscissa of the first target pin satisfies a first preset condition;

a first connecting module 1003, configured to connect the first inlet with the first target pin; and

a second connecting module 1004, configured to connect, according to codes of remaining inlets and codes of remaining pins, the remaining inlets with the remaining pins in a one-to-one correspondence.

Here, the first connecting module is configured to:

connect the first inlet with the first target pin through a first intermediate point, an ordinate of the first intermediate point satisfying:

y1=y_bot+1+2*r.

Here, y_bot refers to ordinates of the multiple first pins, r is a routing turning radius, and 1 is a minimum routing length.

Here, the second connecting module is configured to:

connect each remaining first pin to an inlet having a code corresponding to the remaining first pin respectively through a corresponding second intermediate point and a corresponding third intermediate point, ordinates of the second intermediate point and third intermediate point connected with the remaining first pin satisfying:

y2=((j−p)*y_in+(p−1)*y_bot)/(j−1).

Here, j is a code of the first target pin, p is a code of the remaining first pin, and y_in is an ordinate of the inlet connected with the remaining first pin.

In the apparatus, the multiple pins includes multiple second pins, and the multiple second pins are located on one side of the qubit chain and is perpendicular to the extending direction of the qubit chain.

The second connecting module includes:

a first connecting unit, configured to determine a second inlet from the multiple inlets, and determine a second target pin and a third target pin from the multiple second pins, where a code of the third target pin is adjacent to a code of a first pin farther away from the first target pin, and a distance between an ordinate of a fourth intermediate point corresponding to the second inlet and an ordinate of the second target pin satisfies a second preset condition, where the ordinate of the fourth intermediate point corresponding to the second inlet satisfies:

y3=((j−p1)*y_in1+(p1−1)*y_out1)/(j−1).

where p1 is a code of the second target pin, y_in1 is an ordinate of the second inlet, and y_out1 is an ordinate of the third target pin; and

the first connecting unit is configured to connect the second inlet with the second target pin through the fourth intermediate point; and

a second connecting unit, configured to connect, according to codes of current remaining inlets and codes of remaining second pins, the current remaining inlets with the remaining second pins in a one-to-one correspondence.

Here, the second connecting unit is configured to:

determine a fourth target pin from the multiple first pins, where a code of the fourth target pin is adjacent to a second pin far from the second target pin; and

connect each second pin between the second target pin and the fourth target pin to an inlet having a code corresponding to the second pin respectively through a corresponding fifth intermediate point and a corresponding sixth intermediate point, ordinates of the fifth intermediate point and the sixth intermediate point satisfying:

y4=((j−p2)*y_in2+(p2−1)*y_out1)/(j−1).

Here, p2 is a code of the second pin between the second target pin and the fourth target pin, and y_in2 is an ordinate of an inlet corresponding to the second pin between the second target pin and the fourth target pin.

An abscissa of the sixth intermediate point satisfies:

x1=((p2−i)*x_left+(sep1−p2)*x_out_left)/(sep1−i).

Here, i is the code of the second target pin, x_left is an abscissa of the fourth target pin, sep1 is the code of the fourth target pin, and x_out_left is an abscissa of the second pin.

A third inlet is determined from the multiple inlets, and the third inlet faces a column where the second pins are. A pin corresponding to a code of the third inlet is determined as a fifth target pin.

Each second pin between the second target pin and the fifth target pin is connected to an inlet having a code corresponding to the second pin respectively through a corresponding seventh intermediate point and a corresponding eighth intermediate point, ordinates of the seventh intermediate point and the eighth intermediate point satisfying:

y5=((j−p3)*y_in3+(p3−1)*y_out1)/(j−1).

Here, p3 is a code of the second pin between the second target pin and the fifth target pin, and y_in3 is an ordinate of an inlet corresponding to the second pin between the second target pin and the fifth target pin.

An abscissa of the eighth intermediate point satisfies:

x2=(p3*x_out_left+(i−p3)*x_0)/i.

Here, x_0 is a coordinate of an end point of the qubit chain close to the second pin.

The fifth target pin is connected to the third inlet through a ninth intermediate point, an abscissa of the ninth intermediate point satisfying:

x3=(x_out_left+(i−1)*x_0)/i.

For the functions of the modules in each apparatus in some embodiments of the present disclosure, reference may be made to the corresponding descriptions in the foregoing method, and thus, the details will not be repeatedly described here.

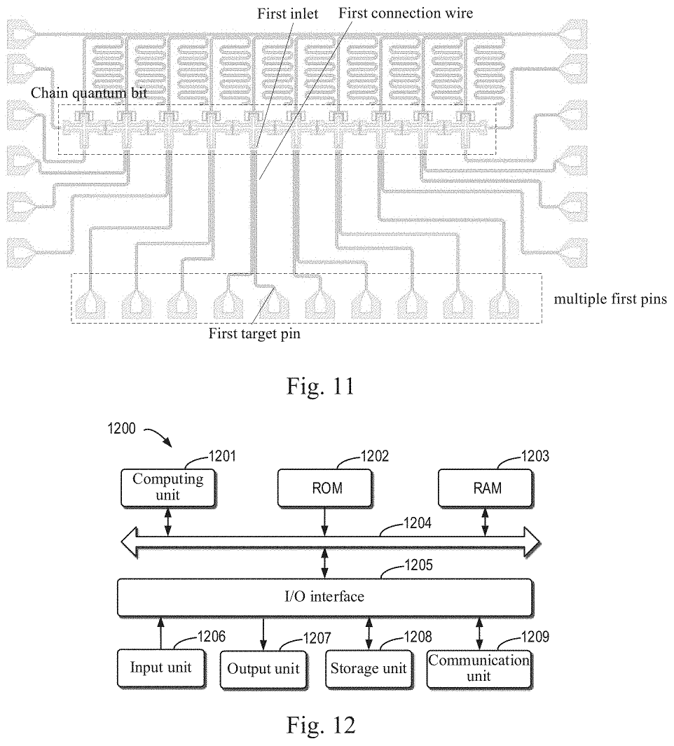

According to some embodiments of the present disclosure, the present disclosure further provides a chain quantum chip, as shown in FIG. 11. The chip includes:

a qubit chain, including multiple qubits, the qubits including at least one inlet;

multiple pins, corresponding to codes of multiple inlets of the qubit chain one by one, where the multiple pins includes multiple first pins, and the multiple first pins are parallel to an extending direction of the qubit chain; and

multiple connection wires, connecting the pins to the inlets having codes corresponding to the pins respectively.

The multiple inlets includes a first inlet, and the multiple first pins includes a first target pin. Here, a distance between an abscissa of the first inlet and an abscissa of the first target pin satisfies a first preset condition, and the multiple connection wires include a first connection wire, connecting the first inlet with the first target pin.

The first connection wire includes:

a first intermediate point, where the first inlet and the first target pin are connected through the first intermediate point, an ordinate of the first intermediate point satisfying:

y1=y_bot+1+2*r.

Here, y_bot refers to ordinates of the multiple first pins, r is a routing turning radius, and 1 is a minimum routing length.

Each connection wire includes:

a second intermediate point and third intermediate point, where each remaining first pin is connected to an inlet having a code corresponding to the remaining first pin respectively through a corresponding second intermediate point and a corresponding third intermediate point, ordinates of the second intermediate point and third intermediate point connected with the remaining first pin satisfying:

y2=((j−p)*y_in+(p−1)*y_bot)/(j−1).

Here, j is a code of the first target pin, p is a code of the remaining first pin, and y_in is an ordinate of the inlet connected with the remaining first pin.

Here, the multiple pins included in the chip includes multiple second pins, and the multiple second pins is located on one side of the qubit chain and is perpendicular to the extending direction of the qubit chain.

Here, the multiple inlets included in the chip includes a second inlet, the multiple second pins includes a second target pin, and a distance between an ordinate of a fourth intermediate point corresponding to the second inlet and an ordinate of the second target pin satisfies a second preset condition, where the ordinate of the fourth intermediate point corresponding to the second inlet satisfies:

y3=((j−p1)*y_in1+(p1−1)*y_out1)/(j−1).

Here, p1 is a code of the second target pin, y_in1 is an ordinate of the second inlet, and y_out1 is an ordinate of a third target pin.

The multiple connection wires include a second connection wire, where the second connection wire passes the fourth intermediate point and connects the second inlet and the second target pin.

Here, the multiple second pins included in the chip includes a third target pin, and a code of the third target pin is adjacent to a code of a first pin far away from the first target pin.

Here, the multiple first pins included in the chip include a fourth target pin, where a code of the fourth target pin is adjacent to a second pin farther from the second target pin.

Each second pin between the second target pin and the fourth target pin is connected to an inlet having a code corresponding to the second pin through a corresponding fifth intermediate point and a corresponding sixth intermediate point respectively, ordinates of the fifth intermediate point and the sixth intermediate point satisfying:

y4=((j−p2)*y_in2+(p2−1)*y_out1)/(j−1).

Here, p2 is a code of the second pin between the second target pin and the fourth target pin, and y_in2 is an ordinate of an inlet corresponding to the second pin between the second target pin and the fourth target pin.

An abscissa of the sixth intermediate point satisfies:

x1=((p2−i)*x_left+(sep1−p2)*x_out_left)/(sep1−i).

Here, i is the code of the second target pin, x_left is an abscissa of the fourth target pin, sep1 is the code of the fourth target pin, and x_out_left is an abscissa of the second pin.

The multiple inlets included in the chip include a third inlet, and the third inlet faces a column where the second pins are. A pin corresponding to a code of the third inlet is determined as a fifth target pin.

Each second pin between the second target pin and the fifth target pin is connected to an inlet corresponding to a code through a corresponding seventh intermediate point and a corresponding eighth intermediate point respectively, ordinates of the seventh intermediate point and the eighth intermediate point satisfying:

y5=((j−p3)*y_in3+(p3−1)*y_out1)/(j−1).

Here, p3 is a code of the second pin between the second target pin and the fifth target pin, and y_in3 is an ordinate of an inlet corresponding to the second pin between the second target pin and the fifth target pin.

An abscissa of the eighth intermediate point satisfies:

x2=(p3*x_out_left+(i−p3)*x_0)/i.

Here, x_0 is a coordinate of an end point of the qubit chain close to the second pin.

The fifth target pin is connected to the third inlet through a ninth intermediate point, an abscissa of the ninth intermediate point satisfying:

x3=(x_out_left+(i−1)*x_0)/i.

In the technical solution of the present disclosure, the acquisition, storage, application, etc. of the personal information of a user all comply with the provisions of the relevant laws and regulations, and do not violate public order and good customs.

According to some embodiments of the present disclosure, the present disclosure further provides an electronic device, a readable storage medium and a computer program product.

FIG. 12 is a schematic block diagram of an example electronic device 1200 that may be used to implement some embodiments of the present disclosure. The electronic device is intended to represent various forms of digital computers such as a laptop computer, a desktop computer, a workstation, a personal digital assistant, a server, a blade server, a mainframe computer, and other appropriate computers. The electronic device may alternatively represent various forms of mobile apparatuses such as personal digital assistant, a cellular telephone, a smart phone, a wearable device and other similar computing apparatuses. The parts shown herein, their connections and relationships, and their functions are only as examples, and not intended to limit implementations of the present disclosure as described and/or claimed herein.

As shown in FIG. 12, the device 1200 includes a computing unit 1201, which can perform various appropriate actions and processes according to a computer program stored in a read only memory (ROM) 1202 or a computer program loaded from the storage unit 1208 into a random access memory (RAM) 1203. In RAM 1203, various programs and data required for the operation of device 1200 can also be stored. The computing unit 1201, Rom 1202, and ram 1203 are connected to each other through a bus 1204. Input/output (I/O) interface 1205 is also connected to bus 1204.

A plurality of components in the device 1200 are connected to the I/O interface 1205, including: an input unit 1206, such as a keyboard, a mouse, etc.; an output unit 1207, such as various types of displays, speakers, and the like; a storage unit 1208, such as a magnetic disk, an optical disk, and the like; and a communication unit 1209, such as a network card, a modem, a wireless communication transceiver, and the like. The communication unit 1209 allows the device 1200 to exchange information/data with other devices through computer networks such as the Internet and/or various telecommunication networks.

The computing unit 1201 may be various general-purpose and/or special-purpose processing components with processing and computing capabilities. Some examples of the computing unit 1201 include, but are not limited to, a central processing unit (CPU), a graphics processing unit (GPU), various dedicated artificial intelligence (AI) computing chips, various computing units that run machine learning model algorithms, digital signal processors (DSPS), and any appropriate processors, controllers, microcontrollers, and the like. The calculation unit 1201 performs the various methods and processes described above, such as matching between the pin and the inlet or calculating any intermediate point. For example, in some embodiments, the method of calculating intermediate point may be implemented as a computer software program that is tangibly contained in a machine-readable medium, such as a storage unit 1208. In some embodiments, part or all of the computer program may be loaded and/or installed on the device 1200 via ROM 1202 and/or communication unit 1209. When the computer program is loaded into RAM 1203 and executed by the computing unit 1201, one or more steps of the method for routing wires on a chain quantum chip described above may be performed. Alternatively, in other embodiments, the computing unit 1201 may be configured to perform the method for routing wires on a chain quantum chip by any other suitable means (e.g., by means of firmware).

Various embodiments of the systems and technologies described above in this paper can be implemented in digital electronic circuit systems, integrated circuit systems, field programmable gate arrays (FPGAs), application specific integrated circuits (ASIC), application specific standard products (ASSP), system on chip (SOC), load programmable logic devices (CPLD), computer hardware, firmware, software, and/or combinations thereof. These various embodiments may include: being implemented in one or more computer programs, the one or more computer programs can be executed and/or interpreted on a programmable system including at least one programmable processor, which can be a special-purpose or general-purpose programmable processor, and can receive data and instructions from the storage system, at least one input device, and at least one output device, and transmitting data and instructions to the storage system, the at least one input device, and the at least one output device.

The program code for implementing the methods of the present disclosure may be written in any combination of one or more programming languages. These program codes can be provided to the processor or controller of general-purpose computer, special-purpose computer or other programmable data processing device, so that when the program code is executed by the processor or controller, the functions/operations specified in the flow chart and/or block diagram are implemented. The program code can be completely executed on the machine, partially executed on the machine, partially executed on the machine and partially executed on the remote machine as a separate software package, or completely executed on the remote machine or server.

In the context of the present disclosure, a machine-readable medium may be a tangible medium that may contain or store a program for use by or in combination with an instruction execution system, apparatus, or device. The machine-readable medium can be a machine-readable signal medium or a machine-readable storage medium. Machine readable media may include, but are not limited to, electronic, magnetic, optical, electromagnetic, infrared, or semiconductor systems, apparatuses, or devices, or any suitable combination of the foregoing. More specific examples of machine-readable storage media may include one or more wire based electrical connections, portable computer disks, hard disks, random access memory (RAM), read only memory (ROM), erasable programmable read only memory (EPROM or flash memory), optical fibers, compact disk read only memory (CD-ROM), optical storage devices, magnetic storage devices, or any suitable combination of the above.

In order to provide interaction with users, the systems and techniques described herein can be implemented on a computer with: a display device for displaying information to users (for example, a CRT (cathode ray tube) or LCD (liquid crystal display) monitor); and a keyboard and a pointing device (e.g., a mouse or a trackball) through which the user can provide input to the computer. Other kinds of devices can also be used to provide interaction with users. For example, the feedback provided to the user may be any form of sensor feedback (e.g., visual feedback, auditory feedback, or tactile feedback); And the input from the user can be received in any form (including acoustic input, voice input or tactile input).

The systems and techniques described herein may be implemented in a computing system including background components (e.g., as a data server), or a computing system including middleware components (e.g., an application server) or a computing system including a front-end component (e.g., a user computer with a graphical user interface or a web browser through which a user can interact with embodiments of the systems and techniques described herein), or a computing system including any combination of the back-end component, the middleware component, the front-end component. The components of the system can be interconnected by digital data communication (e.g., communication network) in any form or medium. Examples of communication networks include local area networks (LANs), wide area networks (WANs), and the Internet.

A computer system may include a client and a server. The client and the server are generally far away from each other and usually interact through communication networks. The relationship between the client and the server is generated by computer programs running on the corresponding computers and having a client server relationship with each other. The server can be a cloud server, a distributed system server, or a blockchain server.

It should be understood that various forms of processes shown above can be used to reorder, add or delete steps. For example, the steps recorded in the present disclosure can be performed in parallel, in sequence, or in different orders, as long as the desired results of the technical solution of the present disclosure can be achieved, which is not limited herein.

The above specific embodiments do not constitute restrictions on the scope of the present disclosure. Those skilled in the art should understand that various modifications, combinations, sub combinations and substitutions can be made according to design requirements and other factors. Any modification, equivalent replacement and improvement made within the spirit and principles of this disclosure shall be included in the scope of protection of this disclosure.

What is claimed is:

1. A method for routing wires on a chain quantum chip, comprising:
encoding, according to a corresponding relationship between a plurality of pins of the chain quantum chip and inlets of a plurality of qubits on a qubit chvain, the plurality of pins and the inlets respectively, wherein the plurality of pins comprises a plurality of first pins, and the plurality of first pins are parallel to an extending direction of the qubit chain;
determining a first inlet from the plurality of inlets, and determining a first target pin from the plurality of first pins, wherein a distance between an abscissa of the first inlet and an abscissa of the first target pin satisfies a first preset condition;
connecting the first inlet with the first target pin; and
connecting, according to codes of remaining inlets and codes of remaining pins, the remaining inlets with the remaining pins in a one-to-one correspondence.

2. The method according to claim 1, wherein the connecting the first inlet with the first target pin comprises:
connecting the first inlet and the first target pin through a first intermediate point, an ordinate of the first intermediate point satisfying:
y1=y_bot+1+2*r,
wherein y_bot refers to an ordinate of the plurality of first pins, r is a routing turning radius, and 1 is a minimum routing length.

3. The method according to claim 1, wherein the connecting, according to codes of remaining inlets and codes of remaining pins, the remaining inlets and the remaining pins in a one-to-one correspondence comprises:
connecting each remaining first pin to an inlet having a code corresponding to the each remaining first pin respectively through a corresponding second intermediate point and a corresponding third intermediate point, ordinates of the second intermediate point and third intermediate point connected with the remaining first pin satisfying:
y2=((j−p)*y_in+(p−1)*y_bot)/(j−1),
wherein j is a code of the first target pin, p is a code of the remaining first pin, and y_in is an ordinate of the inlet connected with the remaining first pin.

4. The method according to claim 1, wherein the plurality of pins comprises a plurality of second pins, and the plurality of second pins is located on one side of the qubit chain and is perpendicular to the extending direction of the qubit chain,
wherein the connecting, according to codes of remaining inlets and codes of remaining pins, the remaining inlets with the remaining pins in a one-to-one correspondence comprises:
determining a second inlet from the plurality of inlets, and determining a second target pin and a third target pin from the plurality of second pins, wherein a code of the third target pin is adjacent to a code of a first pin farther away from the first target pin, and a distance between an ordinate of a fourth intermediate point corresponding to the second inlet and an ordinate of the second target pin satisfies a second preset condition, wherein the ordinate of the fourth intermediate point corresponding to the second inlet satisfies:
y3=((j−p1)*y_in1+(p1−1)*y_out1)/(j−1),
wherein p1 is a code of the second target pin, y_in1 is an ordinate of the second inlet, and y_out1 is an ordinate of the third target pin;
connecting the second inlet with the second target pin through the fourth intermediate point; and
connecting, according to codes of current remaining inlets and codes of remaining second pins, the current remaining inlets with the remaining second pins in a one-to-one correspondence.

5. The method according to claim 4, wherein the connecting, according to codes of current remaining inlets and codes of remaining second pins, the current remaining inlets with the remaining second pins in a one-to-one correspondence comprises:
determining a fourth target pin from the plurality of first pins, wherein a code of the fourth target pin is adjacent to a second pin farther from the second target pin; and
connecting each second pin between the second target pin and the fourth target pin to an inlet having a code corresponding to the each second pin respectively through a corresponding fifth intermediate point and a corresponding sixth intermediate point, ordinates of the fifth intermediate point and the sixth intermediate point satisfying:
y4=((j−p2)*y_in2+(p2−1)*y_out1)/(j−1),
wherein p2 is a code of the second pin between the second target pin and the fourth target pin, and y_in2 is an ordinate of an inlet corresponding to the second pin between the second target pin and the fourth target pin, and an abscissa of the sixth intermediate point satisfying:
x1=((p2−i)*x_left+(sep1−p2)*x_out_left)/(sep1−i),
wherein i is the code of the second target pin, x_left is an abscissa of the fourth target pin, sep1 is the code of the fourth target pin, and x_out_left is an abscissa of the second pin.

6. The method according to claim 4, wherein the connecting, according to codes of current remaining inlets and codes of remaining second pins, the current remaining inlets and the remaining second pins in a one-to-one correspondence comprises:
determining a third inlet from the plurality of inlets, and determining a pin corresponding to a code of the third inlet as a fifth target pin, wherein the third inlet faces a column where the second pins are;
connecting each second pin between the second target pin and the fifth target pin to an inlet having a code corresponding to the each second pin respectively through a corresponding seventh intermediate point and a corresponding eighth intermediate point, ordinates of the seventh intermediate point and the eighth intermediate point satisfying:
y5=((j−p3)*y_in3+(p3−1)*y_out1)/(j−1),
wherein p3 is a code of the second pin between the second target pin and the fifth target pin, and y_in3 is an ordinate of an inlet corresponding to the second pin between the second target pin and the fifth target pin, an abscissa of the eighth intermediate point satisfying:
x2=(p3*x_out_left+(i−p3)*x_0)/i,
wherein x_0 is a coordinate of an end point of the qubit chain closer to the second pin; and
connecting the fifth target pin to the third inlet through a ninth intermediate point, an abscissa of the ninth intermediate point satisfying:
x3=(x_out_left+(i−1)*x_0)/i.

7. An apparatus for routing wires on a chain quantum chip, comprising:
at least one processor; and
a storage device storing instructions,
wherein the instructions when executed by the at least one processor cause the at least one processor to perform operations comprising:
encoding, according to a corresponding relationship between a plurality of pins of the chain quantum chip and inlets of a plurality of qubits on a qubit chain, the plurality of pins and a plurality of inlets respectively, wherein the plurality of pins comprises a plurality of first pins, and the plurality of first pins is parallel to an extending direction of the qubit chain;
determining a first inlet from the plurality of inlets, and determining a first target pin from the plurality of first pins, wherein a distance between an abscissa of the first inlet and an abscissa of the first target pin satisfies a first preset condition;
connecting the first inlet with the first target pin; and
connecting, according to codes of remaining inlets and codes of remaining pins, the remaining inlets with the remaining pins in a one-to-one correspondence.

8. The apparatus according to claim 7, wherein the connecting the first inlet with the first target pin comprises:
connecting the first inlet and the first target pin through a first intermediate point, an ordinate of the first intermediate point satisfying:
y1=y_bot+1+2*r,
wherein y_bot refers to an ordinate of the plurality of first pins, r is a routing turning radius, and 1 is a minimum routing length.

9. The apparatus according to claim 7, wherein the connecting, according to codes of remaining inlets and codes of remaining pins, the remaining inlets and the remaining pins in a one-to-one correspondence comprises:
connecting each remaining first pin to an inlet having a code corresponding to the each remaining first pin respectively through a corresponding second intermediate point and a corresponding third intermediate point, ordinates of the second intermediate point and third intermediate point connected with the remaining first pin satisfying:
y2=((j−p)*y_in+(p−1)*y_bot)/(j−1),
wherein j is a code of the first target pin, p is a code of the remaining first pin, and y_in is an ordinate of the inlet connected with the remaining first pin.

10. The apparatus according to claim 7, wherein the plurality of pins comprises a plurality of second pins, and the plurality of second pins is located on one side of the qubit chain and is perpendicular to the extending direction of the qubit chain,
wherein the connecting, according to codes of remaining inlets and codes of remaining pins, the remaining inlets with the remaining pins in a one-to-one correspondence comprises:
determining a second inlet from the plurality of inlets, and determining a second target pin and a third target pin from the plurality of second pins, wherein a code of the third target pin is adjacent to a code of a first pin farther away from the first target pin, and a distance between an ordinate of a fourth intermediate point corresponding to the second inlet and an ordinate of the second target pin satisfies a second preset condition, wherein the ordinate of the fourth intermediate point corresponding to the second inlet satisfies:
y3=((j−p1)*y_in1+(p1−1)*y_out1)/(j−1),
wherein p1 is a code of the second target pin, y_in1 is an ordinate of the second inlet, and y_out1 is an ordinate of the third target pin; and
connecting the second inlet with the second target pin through the fourth intermediate point;
connecting, according to codes of current remaining inlets and codes of remaining second pins, the current remaining inlets with the remaining second pins in a one-to-one correspondence.

11. The apparatus according to claim 10, wherein the connecting, according to codes of current remaining inlets and codes of remaining second pins, the current remaining inlets with the remaining second pins in a one-to-one correspondence comprises:
determining a fourth target pin from the plurality of first pins, wherein a code of the fourth target pin is adjacent to a second pin farther from the second target pin; and
connecting each second pin between the second target pin and the fourth target pin to an inlet having a code corresponding to the each second pin respectively through a corresponding fifth intermediate point and a corresponding sixth intermediate point, ordinates of the fifth intermediate point and the sixth intermediate point satisfying:
y4=((j−p2)*y_in2+(p2−1)*y_out1)/(j−1),
wherein p2 is a code of the second pin between the second target pin and the fourth target pin, and y_in2 is an ordinate of an inlet corresponding to the second pin between the second target pin and the fourth target pin, and an abscissa of the sixth intermediate point satisfying:
x1=((p2−i)*x_left+(sep1−p2)*x_out_left)/(sep1−i),
wherein i is the code of the second target pin, x_left is an abscissa of the fourth target pin, sep1 is the code of the fourth target pin, and x_out_left is an abscissa of the second pin.

12. The apparatus according to claim 10, wherein the connecting, according to codes of current remaining inlets and codes of remaining second pins, the current remaining inlets and the remaining second pins in a one-to-one correspondence comprises:
determining a third inlet from the plurality of inlets, and determine a pin corresponding to a code of the third inlet as a fifth target pin, wherein the third inlet faces a column where the second pins are;
connecting each second pin between the second target pin and the fifth target pin to an inlet having a code corresponding to the each second pin respectively through a corresponding seventh intermediate point and a corresponding eighth intermediate point, ordinates of the seventh intermediate point and the eighth intermediate point satisfying:
y5=((j−p3)*y_in3+(p3−1)*y_out1)/(j−1),
wherein p3 is a code of the second pin between the second target pin and the fifth target pin, and y_in3 is an ordinate of an inlet corresponding to the second pin between the second target pin and the fifth target pin, and an abscissa of the eighth intermediate point satisfying:
x2=(p3*x_out_left+(i−p3)*x_0)/i,
wherein x_0 is a coordinate of an end point of the qubit chain closer to the second pin; and
connecting the fifth target pin to the third inlet through a ninth intermediate point, an abscissa of the ninth intermediate point satisfying:
x3=(x_out_left+(i−1)*x_0)/i.

13. A chain quantum chip, comprising:
a qubit chain, comprising a plurality of qubits, wherein the qubit in the plurality qubit comprises at least one inlet;
a plurality of pins, corresponding to codes of a plurality of inlets of the qubit chain one by one, wherein the plurality of pins comprises a plurality of first pins, and the plurality of first pins is parallel to an extending direction of the qubit chain; and
a plurality of connection wires, connecting the pins corresponding to the codes with the inlets respectively,
wherein the plurality of inlets comprises a first inlet, and the plurality of first pins comprises a first target pin, wherein a distance between an abscissa of the first inlet and an abscissa of the first target pin satisfies a first preset condition, and the plurality of connection wires comprises a first connection wire, connecting the first inlet with the first target pin.

14. The chip according to claim 13, wherein the first connection wire comprises:
a first intermediate point, wherein the first inlet and the first target pin are connected through the first intermediate point, an ordinate of the first intermediate point satisfying:
y1=y_bot+1+2*r,
wherein y_bot refers to an ordinate of the plurality of first pins, r is a routing turning radius, and 1 is a minimum routing length.

15. The chip according to claim 13, wherein the connection wires comprise:
a second intermediate point and third intermediate point, wherein each remaining first pin is connected to an inlet having a code corresponding to the each remaining first pin respectively through a corresponding second intermediate point and a corresponding third intermediate point, ordinates of the second intermediate point and third intermediate point connected with the remaining first pin satisfying:
y2=((j−p)*y_in+(p−1)*y_bot)/(j−1),
wherein j is a code of the first target pin, p is a code of the remaining first pin, and y_in is an ordinate of the inlet connected with the remaining first pin.

16. The chip according to claim 13, wherein the plurality of pins comprises a plurality of second pins, and the plurality of second pins is located on one side of the qubit chain and is perpendicular to the extending direction of the qubit chain,
the plurality of second pins comprises a third target pin, and a code of the third target pin is adjacent to a code of a first pin farther away from the first target pin,
and the plurality of inlets comprises a second inlet, the plurality of second pins comprises a second target pin, and a distance between an ordinate of a fourth intermediate point corresponding to the second inlet and an ordinate of the second target pin satisfies a second preset condition, wherein the ordinate of the fourth intermediate point corresponding to the second inlet satisfies:
y3=((j−p1)*y_in1+(p1−1)*y_out1)/(j−1),
wherein p1 is a code of the second target pin, y_in1 is an ordinate of the second inlet, and y_out1 is an ordinate of the third target pin; and
the plurality of connection wires comprise a second connection wire, wherein the second connection wire passes the fourth intermediate point and connects the second inlet and the second target pin.

17. The chip according to claim 16, wherein the plurality of first pins comprises a fourth target pin, wherein a code of the fourth target pin is adjacent to a second pin farther from the second target pin, and
each second pin between the second target pin and the fourth target pin is connected to an inlet having a code corresponding to the each second pin respectively through a corresponding fifth intermediate point and a corresponding sixth intermediate point, ordinates of the fifth intermediate point and the sixth intermediate point satisfying:
y4=((j−p2)*y_in2+(p2−1)*y_out1)/(j−1),
wherein p2 is a code of the second pin between the second target pin and the fourth target pin, and y_in2 is an ordinate of an inlet corresponding to the second pin between the second target pin and the fourth target pin, and an abscissa of the sixth intermediate point satisfying:
x1=((p2−i)*x_left+(sep1−p2)*x_out_left)/(sep1−i),
wherein i is the code of the second target pin, x_left is an abscissa of the fourth target pin, sep1 is the code of the fourth target pin, and x_out_left is an abscissa of the second pin.

18. The chip according to claim 16, wherein the plurality of inlets comprises a third inlet, and a pin corresponding to a code of the third inlet is determined as a fifth target pin, wherein the third inlet faces a column where the second pins are,
and each second pin between the second target pin and the fifth target pin is connected to an inlet having a code corresponding to the each second pin respectively through a corresponding seventh intermediate point and a corresponding eighth intermediate point, ordinates of the seventh intermediate point and the eighth intermediate point satisfying:
y5=((j−p3)*y_in3+(p3−1)*y_out1)/(j−1),
wherein p3 is a code of the second pin between the second target pin and the fifth target pin, and y_in3 is an ordinate of an inlet corresponding to the second pin between the second target pin and the fifth target pin, and an abscissa of the eighth intermediate point satisfying:
x2=(p3*x_out_left+(i−p3)*x_0)/i,
wherein x_0 is a coordinate of an end point of the qubit chain closer to the second pin, and
the fifth target pin is connected to the third inlet through a ninth intermediate point, an abscissa of the ninth intermediate point satisfying:
x3=(x_out_left+(i−1)*x_0)/i.

19. A non-transitory computer readable storage medium, storing a computer instruction, wherein the computer instruction is used to cause a computer to perform the method according to claim 1.
